(19) United States
(12) Patent Application Publication
(10) Pub. No.: US 2014/0062530 A1
(43) Pub. Date: Mar. 6, 2014

(54) SWITCHING MECHANISM OF MAGNETIC STORAGE CELL AND LOGIC UNIT USING CURRENT INDUCED DOMAIN WALL MOTIONS

(71) Applicants: Guo-Xing Miao, Somerville, MA (US); Jagadeesh S. Moodera, Somerville, MA (US)

(72) Inventors: Guo-Xing Miao, Somerville, MA (US); Jagadeesh S. Moodera, Somerville, MA (US)

(73) Assignee: MASSACHUSETTS INSTITUTE OF TECHNOLOGY, Cambridge, MA (US)

(21) Appl. No.: 13/044,045

(22) Filed: Mar. 9, 2011

Related U.S. Application Data
(60) Provisional application No. 61/314,256, filed on Mar. 16, 2010.

(51) Int. Cl. G11C 11/16; H01L 43/12

(52) U.S. Cl. CPC G11C 11/16; H01L 43/12
USPC 326/37; 438/3; 365/158

(57) ABSTRACT

A magnetic memory cell is provided that includes a free layer that is pinned on both of its sides to form one or more domain wall structures. The one or more domain wall structures define one or more logic states by controlling the motion of the one or more domain wall structures.

### PRIORITY INFORMATION

The present invention claims priority to U.S. Provisional application No. 61/314,256, filed on Mar. 16, 2010. The contents of which are incorporated herein by reference in its entirety.

### SPONSORSHIP INFORMATION

This invention was made with government funding under Grant No. N00014-06-1-0235, awarded by the Office of Naval Research and under Grant No. W911NF-08-1-0087, awarded by the Army Research Office. The government has certain rights in this invention.

### BACKGROUND OF THE INVENTION

The invention is related to the field of magnetic storage cells, and in particular to a switching mechanism for magnetic storage cells and logic units using current induced domain wall motions.

A rewritable nonvolatile memory using a magnetic random access memory (hereinafter called an MRAM) including magnetoresistive effect elements are commonly used. The MRAM uses combinations of magnetization directions of two magnetic layers to memorize information and to read the information. The device detects resistance changes, i.e., current changes or voltage changes, between the resistance with the magnetization directions of the two magnetic layers being parallel with each other and the resistance with the magnetization directions of the two magnetic layers being anti-parallel with each other.

The magnetoresistive effect elements forming the MRAM are known as the GMR (Giant Magnetoresistive) element and the TMR (Tunneling Magnetoresistive) element. Of them, the TMR element, which provides large resistance changes, is commonly used in the MRAM. The TMR element includes two ferromagnetic layers laid one on another with a tunnel insulating film formed therebetween, and utilizes the phenomenon that the tunnel current that flows between the magnetic layers via the tunnel insulating film changes based on relationships of the magnetization directions of the two ferromagnetic layers. That is, the TMR element has low element resistance when the magnetization directions of the two ferromagnetic layers are parallel with each other, and has high element resistance when both are anti-parallel with each other. These two states are related to data “0” and data “1” to use the TMR element as a memory device.

The spin transfer torque based switching mechanism uses a magnetoresistive effect element having two magnetic layers with an insulating film or a non-magnetic metal layer formed therebetween, which is similar to the GMR element and the TMR element. However, in the spin transfer torque based switching mechanism in which current flows perpendicularly to the film surface, large current must flow repeatedly. Accordingly, dielectric breakdown and pin holes are often generated in the barrier layer, and the interconnections are often broken by the electromigration. This causes degradation in many memory devices.

### SUMMARY OF THE INVENTION

According to one aspect of the invention, there is provided a magnetic memory cell. The magnetic memory cell includes a free layer that is pinned on both of its sides to form one or more domain wall structures. The one or more domain wall structures define one or more logic states by controlling the motion of the one or more domain wall structures.

According to another aspect of the invention, there is provided a method of forming a memory cell. The method includes providing a free layer that is pinned on both of its sides. Also, the method includes forming one or more domain wall structures. The one or more domain wall structures define one or more logic states by controlling the motion of the one or more domain wall structures

### BRIEF DESCRIPTION OF THE DRAWINGS

FIG. 1 is a schematic diagram illustrating a magnetic memory and/or logic device used in accordance with the invention; and

FIGS. 2A-2B are schematic diagrams illustrating the magnetic memory and/or logic device based on current induced domain wall motions and nanoparticle assisted switchings.

### DETAILED DESCRIPTION OF THE INVENTION

The invention involves a switching mechanism for magnetic memory and logic devices. Instead of using the conventional magnetic field switching or spin transfer torque (STT) switching, the inventive device can be toggled between the “0” and “1” states by controlled motion of domain walls.

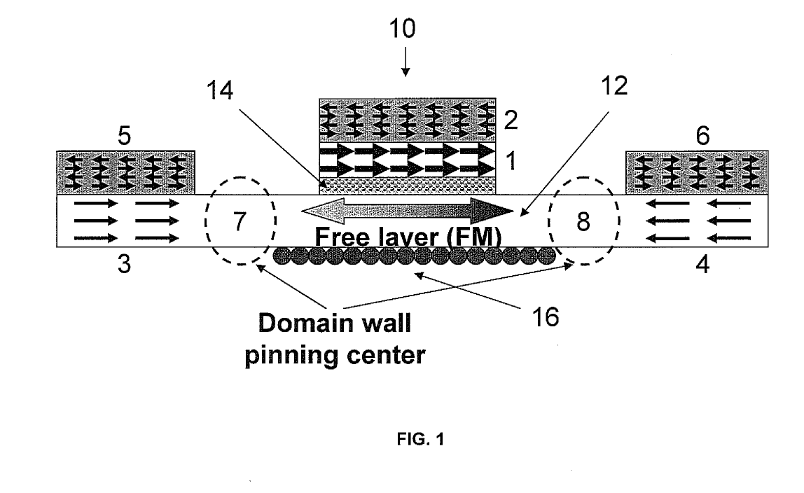

FIG. 1 illustrates how such a writing process works. In a GMR or TMR based memory/logic unit 10, a ferromagnetic (FM) layer 1 is pinned by current exchange biasing from an anti-ferromagnetic (AFM) layer 2. Another FM or free layer 12 is also provided. The free layer 12 includes regions 7, 8 defining domain wall pinning centers, and pinned regions 3, 4. The free layer 12 is pinned on both of its sides as shown by regions 7, 8, which define the position of a domain wall. An AFM layer 5 pins region 3 of the free layer 12, and an AFM layer 6 pins region 4 of the free layer 12.

The memory/logic unit 10 can either be at its “0” or “1” state depending on the position of the domain wall pinning centers positioned within regions 7 or 8 on the free layer 12. In particular, the memory/logic unit 10 can be at its low state “0” when a domain wall is defined at region 8 on the free layer 12, and it is at its high state “1” when the domain wall 10 is pinned at region 7 on the free layer. A TMR or GMR stack 14 on top of the free layer 12 is used in reading the bit information.

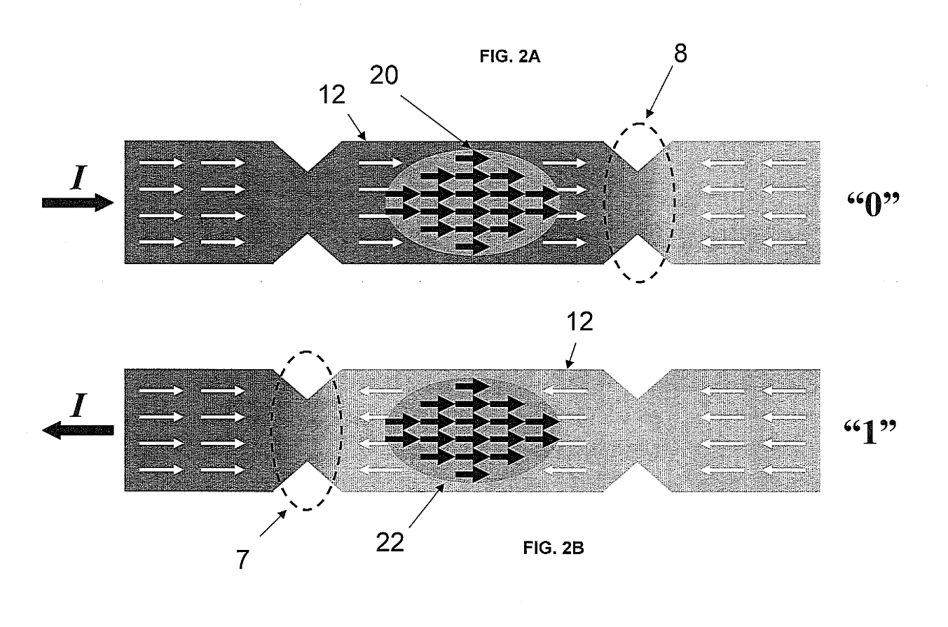

To write such a bit, a current needs to be driven across the free layer 12 to its respective domain wall pinning centers defined by regions 7, 8. FIG. 2A shows that if a large enough current pulse I flow from left to right, the free layer 12 is pinned at region 8, and a bit of “0” will be written. Alternatively, if the current I flows from right to left, the free layer 12 is pinned at region 7, and a bit of “1” will be written, as shown in FIG. 2B. In such a writing mechanism, the large writing current does not go through the MTJ barriers, and damage to the barriers is avoided. The writing current is directly proportional to the thickness of the free layer 12, and can be tuned to any desired value. On the other hand, the high density of a STT based memory cell and/or logic is still maintained. Another main advantage is that the current density limitation and the high probability of device breakdown in conventional STT based memory cell are overcome. It will be appreciated that regions 20, 22 show the current in the free layer 12 and their respective “0” or “1” state.

To make the switching process even easier, the invention introduces an additional layer 16 of domain nucleation assistance as shown in FIG. 1. The domain nucleation assistance layer 16 can include isolated magnetic nanoparticles or soft magnetic clusters, and do not have to be in direct contact with the free layer 12. Their function is to induce inhomogeneity around the free layer 12 and thus assists the formation of domain walls, as well as lowering the required switching current.

The reading of the bit information can be accomplished using the GMR or TMR effects. The domain wall pinning center regions 7, 8 can be formed by any technique such as creating notches or local ion damage on the free layer 12. The pinned regions 3 and 4 are to assist in domain wall nucleation. However, they are not limited to the above-proposed techniques. Other mechanisms that can read the bit information can be used in accordance with the invention. The free layer 12 is not limited to be planar, it can be extended vertically in order to gain further memory and/or logic density.

Although the present invention has been shown and described with respect to several preferred embodiments thereof, various changes, omissions and additions to the form and detail thereof, may be made therein, without departing from the spirit and scope of the invention.

What is claimed is:

1. A magnetic memory cell comprising a free layer that is pinned on both of its sides to form one or more domain wall structures, said one or more domain wall structures define one or more logic states by controlling the motion of the one or more domain wall structures.

2. The magnetic memory cell of claim 1, wherein said free layer is positioned near domain wall centers.

3. The magnetic memory cell of claim 1, wherein said one or more domain wall structures receive a current to define the motion of the one or more domain wall structures

4. The magnetic memory cell of claim 1, wherein said one or more logic states define a binary or multibyte system.

5. The magnetic memory cell of claim 1, wherein said free layer is positioned near a plurality of domain nucleation assistances.

6. The magnetic memory cell of claim 1, wherein said domain nucleation assistances comprise isolated magnetic nanoparticles or local electric/magnetic field modulations.

7. The magnetic memory cell of claim 1, wherein said domain nucleation assistances induce inhomogeneity around the free layer and assisting the formation and propagation of the one or more domain wall structures.

8. A logic device comprising a free layer that is pinned on both of its sides to form one or more domain wall structures, said one or more domain wall structures define one or more logic states by controlling the motion of the domain wall structures.

9. The logic device of claim 8, wherein said free layer is positioned near domain wall centers.

10. The logic device of claim 8, wherein said one or more domain wall structures receive a current to define the motion of the one or more domain wall structures

11. The logic device of claim 8, wherein said one or more logic states define a binary or multibyte system.

12. The logic device of claim 8, wherein said free layer is positioned near a plurality of domain nucleation assistances.

13. The logic device of claim 8, wherein said domain nucleation assistances comprise isolated magnetic nanoparticles or local electric/magnetic field modulations.

14. The logic device of claim 8, wherein said domain nucleation assistances induce inhomogeneity around the free layer and assisting the formation and propagation of the one or more domain wall structures.

15. A method of forming a memory cell comprising:
providing a free layer that is pinned on both of its sides; and
forming one or more domain wall structures, said one or more domain wall structures define one or more logic states by controlling the motion of the one or more domain wall structures.

16. The method of claim 15, wherein said free layer is positioned near domain wall centers.

17. The method of claim 15, wherein said one or more domain wall structures receive a current to define the motion of the one or more domain wall structures

18. The method of claim 15, wherein said one or more logic states define a binary or multibyte system.

19. The method of claim 15, wherein said free layer is positioned near a plurality of domain nucleation assistances.

20. The method of claim 15, wherein said domain nucleation assistances comprise isolated magnetic nanoparticles or local electric/magnetic field modulations.

21. The method of claim 15, wherein said domain nucleation assistances induce inhomogeneity around the free layer and assisting the formation and propagation of the one or more domain wall structures.
